(19) United States
(12) Patent Application Publication
(10) Pub. No.: US 2022/0262431 A1
(43) Pub. Date: Aug. 18, 2022

(54) DETECTED THRESHOLD VOLTAGE STATE DISTRIBUTION OF FIRST AND SECOND PASS PROGRAMED MEMORY PAGES

(71) Applicant: Intel NDTM US LLC, Santa Clara, CA (US)

(72) Inventors: Sagar Upadhyay, Folsom, CA (US); Aliasgar S. Madraswala, Folsom, CA (US); John Egler, Folsom, CA (US)

(21) Appl. No.: 17/737,461

(22) Filed: May 5, 2022

(51) Int. Cl. G11C 11/56; G11C 16/04; G11C 16/10; G11C 16/26

(52) U.S. Cl. CPC G11C 11/5628; G11C 11/5642; G11C 11/5671; G11C 2216/20; G11C 16/10; G11C 16/26; G11C 16/0483

(57) ABSTRACT

Systems, apparatuses, and methods provide for technology for distinguishing an erased state, a first pass programmed state, and a second pass programmed state of a memory page. A threshold voltage state verify sense is performed. A memory page status is determined based on the threshold voltage state verify sense. The memory page status is one of erased, programmed with first pass data, and programmed with second pass data based on the threshold voltage state verify sense. A program continuation is performed after a program interruption based on the memory page status.

### TECHNICAL FIELD

Embodiments generally relate to memory structures. More particularly, embodiments relate to detection of threshold voltage (Vₜ) state distribution of memory pages to improve performance in non-volatile memory (NVM) structures.

### BACKGROUND

In solid state drives (SSDs), multi-level NAND-type flash memory (“NAND memory”) may be organized into multiple cells, with each cell containing multiple bits of data. In such a case, cells are typically programmed into one of 2^{N} possible levels to store N bits of information. To read this data, a series of read operations at predetermined read levels (e.g., a subset of 2^{N}-1 read levels) are performed. For example, in a tri-level cell (TLC) NAND device, programming is achieved by placing the threshold voltage (Vₜ) of each cell into one of eight possible threshold voltage levels (L0, L1, . . . , L7) based on three bits of data that is written into the cell. The threshold voltage may be achieved by applying a series of program pulses with increasing magnitude to a control gate of targeted NAND cells, with each pulse being followed by a series of verify steps to compare the threshold voltage of the targeted NAND cells against specific verify levels.

To minimize potential disturbances from Floating Gate—Floating Gate couplings, a multi-level program is often performed in two passes. For example, a tri-level cell (TLC) program can be performed as 2-8 Program and a quad-level cell (QLC) program can be performed as 4-16 Program.

Some existing memory systems may use a combination of Erased Page Check and Flag Check features. For example, such a combination of Erased Page Check and Flag Check features may be utilized to detect if a page is erased, programmed with a 1^{st}-pass programming only, or programmed with both a 1^{st}-pass and a 2^{nd}-pass programming. This typically requires reserving some Columns/Bytes of a page as “Flag-Bytes.” Such Flag-Bytes typically need to be programmed with certain data during a Program-Operation.

### BRIEF DESCRIPTION OF THE DRAWINGS

The various advantages of the embodiments will become apparent to one skilled in the art by reading the following specification and appended claims, and by referencing the following drawings, in which:

FIG. 1 is a diagram of an example of a program level distribution for a quad level cell according to an embodiment;

FIG. 2 is a flowchart of an example of a method for management of memory page programming according to an embodiment;

FIG. 3 is an illustration of an example of a semiconductor package apparatus according to an embodiment; and

FIG. 4 is a block diagram of an example of a performance-enhanced computing system according to an embodiment.

### DESCRIPTION OF EMBODIMENTS

As discussed above, some existing memory systems may use a combination of Erased Page Check and Flag Check features. For example, such a combination of Erased Page Check and Flag Check features may be utilized to detect if a page is erased, programmed with a 1^{st}-pass programming only, or programmed with both a 1^{st}-pass and a 2^{nd}-pass programming. This typically requires reserving some Columns/Bytes of a page as “Flag-Bytes.” Such Flag-Bytes typically need to be programmed with certain data during a Program-Operation.

Disadvantageously, such a combination of Erased Page Check and Flag Check features typically involves programming of the Flag-Bytes to support the Flag-Check feature. Accordingly, such memory systems are typically required to use a combination of two different features to determine the threshold voltage (Vₜ) state distribution of a Page. Such a programming of the Flag-Bytes to support the Flag-Check feature typically costs additional typical page programming time (tPROG) time (e.g., by approximately 0.25%) as well as consuming additional intelligent Read-Only Memory (IROM) area (e.g., approximately 0.5% of IROM area).

Advantageously, and as will be discussed in further detail below, if these reserved flag columns/bytes are instead used as redundant columns, then NAND yield can be improved. For example, some implementations herein introduce a method that detects threshold voltage (Vₜ) state distribution of a memory page in an efficient manner.

In some implementations, for Power-Loss-Interrupt during Write-in-Progress, SSDs may need to determine the Vt State of a memory page. For example, the Vt State of a memory page may be utilized to determine if a memory page is Erased, programmed with first pass data only, or programmed with second pass data. For a memory page in a quad-level cell (QLC) block, the Vt State may be utilized to determine if a memory page is Erased, programmed with 4-Distribution, or Programmed with 16-Distribution) for Program-Continuation. It will be appreciated that the techniques described herein are applicable to many types of NAND memory cells (e.g., tri-level cells (TLC), quad-level cells (QLC), penta-level cells (PLC), and the like).

Some implementations herein, once enabled after an Erased Page Check fails, perform a verify-sense on a “Second from the Last” programming-level (e.g., L14 for QLC, L6 for TLC, and the like), compare the number of passing cells with a trimmable threshold, and sets a Status-Register bit0 if the number of passing cells are higher than the trimmable threshold to indicate that the page is programmed with both 1^{st}-pass and 2^{nd}-pass data.

Advantageously, advancements of some implementations herein include combining an Erased Page Check with a Vt-State Detection of a programmed memory page using just a single NAND command. Accordingly, some implementations herein minimize system firmware (FW) overhead by providing the Vt State of a memory page with just one single command. For example, such a single NAND command sets two Status-Register bits to indicate each of the following: Erased, programmed with 1^{st}-Pass, or programmed with 2^{nd}-pass status of a page.

Additionally, some implementations herein advantageously do not use Flag-Bytes to detect Vt status of a programmed-page, which allows freeing up such Program-Flag columns/bytes for better and more efficient uses. Such an advantage improves the tPROG efficiency by 0.25%, and IROM usage by 0.5%.

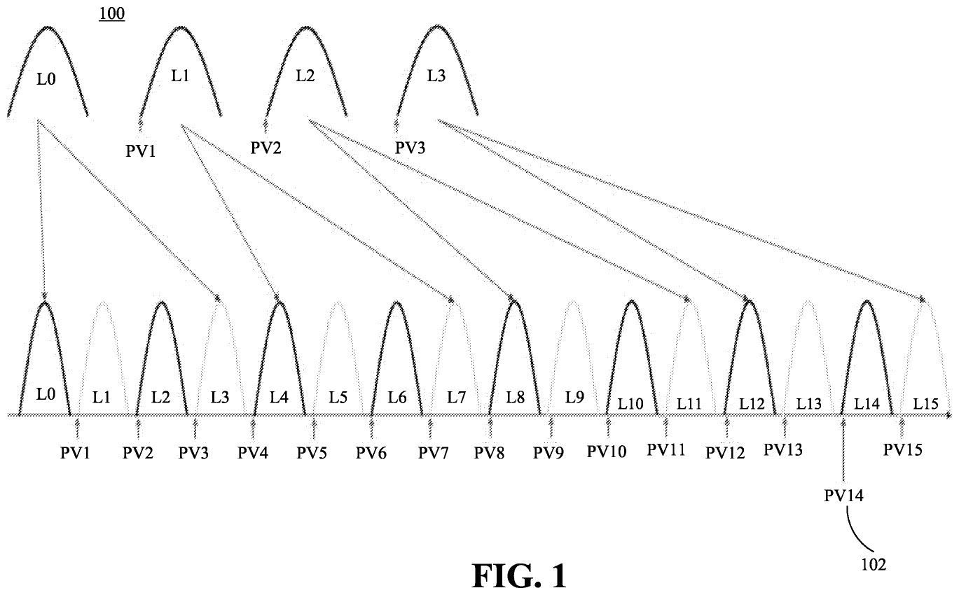

FIG. 1 is a diagram of an example of a program level distribution 100 for a quad level cell according to an embodiment. As illustrated, FIG.1 shows a QLC 4-16 level distribution.

Some implementations herein allow a user to distinguish 1^{st}-pass and 2^{nd}-pass states of a Programmed Page after the user identifies that the current page is in non-erased state. For example, a threshold voltage state verify sense 102 is performed. A memory page status is determined based on the threshold voltage state verify sense. The memory page status is one of erased, programmed with first pass data, and programmed with second pass data based on the threshold voltage state verify sense. A program continuation is performed after a program interruption based on the memory page status.

As discussed above, some implementations herein include combining an Erased Page Check with a Vt-State Detection of a programmed memory page using just a single NAND command. For example, a user can set a feature prior to issuing a Read command to implement some examples herein. Once the feature is set, user should either issue a Top-Page Read (for QLC) or an Extra-Page Read (for TLC) to detect the status of the Vt programmed. This feature will then perform a verify sense on a level (e.g., on Level14 for QLC, Level6 for TLC, or the like) to identify the number of cells programmed above that level.

After the threshold voltage state verify sense 102 is performed, a number of cells programmed above the sense level are calculated and compared against a trimmable criteria. As used herein, the term “trimmable criteria” or “trimmable threshold” refers to a threshold based on anticipated defective memory cells per level. Such a trimmable threshold is utilized herein to avoid a false positive result that might incorrectly identify a programmed memory page due to defective memory cells.

If the number of programmed cells above the threshold voltage state verify sense 102 level are higher than the trimmable threshold, a Status-Register (SR) bit0 is set to “1” which indicates that the current page is programmed with 2^{nd}-pass data, otherwise a Status-Register bit0 stays “0” indicating that the current page is programmed with 1^{st}-pass only. For example, at the end of the Read-Operation: if SR[0]=0 then the page is programmed with 1^{st}-pass data only (e.g., 4-distribution for QLC), or if SR[0]=1 then the page is programmed with 2^{nd}-pass data as well (e.g., 16-distribution for QLC).

As summarized in table 1 and table 2 below, some implementations herein addressed to a Top Page (e.g., (QLC WL)/Extra Page (edge TLC WL)) returns a PASS status for partially program (e.g., for 4 state (QLC), 2 state (edge TLC), or the like) or a FAIL status for fully programmed (e.g., 16 state (QLC WL), 8 state (edge TLC WL), or the like).

TABLE 1
Table 1 for QLC (4-16):

| | EPC - r_L1 sense | EPC - r_L14 sense |
|---|---|---|
| | (LP page address) | (TP page address) |
| All erase | Pass | Pass |
| 4-state | Fail | Pass |
| program | | |
| 16-state | Fail | Fail |
| program | | |
| INVALID | Pass | Fail |

TABLE 2
Table 2 for TLC (2-8):

| | EPC - r_L1 sense | EPC - r_L6 sense |
|---|---|---|
| | (LP page address) | (XP page address) |
| All erase | Pass | Pass |
| 2-state | Fail | Pass |
| program | | |
| 8-state | Fail | Fail |
| program | | |
| INVALID | Pass | Fail |

Examples of multi-deck or multi-layer memory architectures include multi-deck crosspoint memory and 3D NAND memory. Different memory technologies have adopted different terminology. For example, a deck in a crosspoint memory device typically refers to a layer of memory cell stacks that can be individually addressed. In contrast, a 3D NAND memory device is typically said to include a NAND array that includes many layers, as opposed to decks. In 3D NAND, a deck may refer to a subset of layers of memory cells (e.g., two decks of X-layers to effectively provide a 2X-layer NAND device). The term “deck” will be used throughout this disclosure to describe a layer, a tier, or a similar portion of a three-dimensional memory.

For example, a memory device may include non-volatile memory and/or volatile memory. Non-volatile memory is a storage medium that does not require power to maintain the state of data stored by the medium. In one embodiment, the memory structure is a block addressable storage device, such as those based on NAND or NOR technologies. A storage device may also include future generation nonvolatile devices, such as a three-dimensional (3D) crosspoint memory device, or other byte addressable write-in-place nonvolatile memory devices. In one embodiment, the storage device may be or may include memory devices that use silicon-oxide-nitride-oxide-silicon (SONOS) memory, electrically erasable programmable read-only memory (EEPROM), chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thiristor based memory device, or a combination of any of the above, or other memory. The term “storage device” may refer to the die itself and/or to a packaged memory product. In some embodiments, 3D crosspoint memory may comprise a transistor-less stackable cross point architecture in which memory cells sit at the intersection of word lines and bit lines and are individually addressable and in which bit storage is based on a change in bulk resistance. In particular embodiments, a memory module with non-volatile memory may comply with one or more standards promulgated by the Joint Electron Device Engineering Council (JEDEC), such as JESD235, JESD218, JESD219, JESD220-1, JESD223B, JESD223-1, or other suitable standard (the JEDEC standards cited herein are available at jedec.org).

Volatile memory is a storage medium that requires power to maintain the state of data stored by the medium. Examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular embodiments, DRAM of the memory modules complies with a standard promulgated by JEDEC, such as JESD79F for Double Data Rate (DDR) SDRAM, JESD79-2F for DDR2 SDRAM, JESD79-3F for DDR3 SDRAM, or JESD79-4A for DDR4 SDRAM (these standards are available at jedec.org). Such standards (and similar standards) may be referred to as DDR-based standards and communication interfaces of the storage devices that implement such standards may be referred to as DDR-based interfaces.

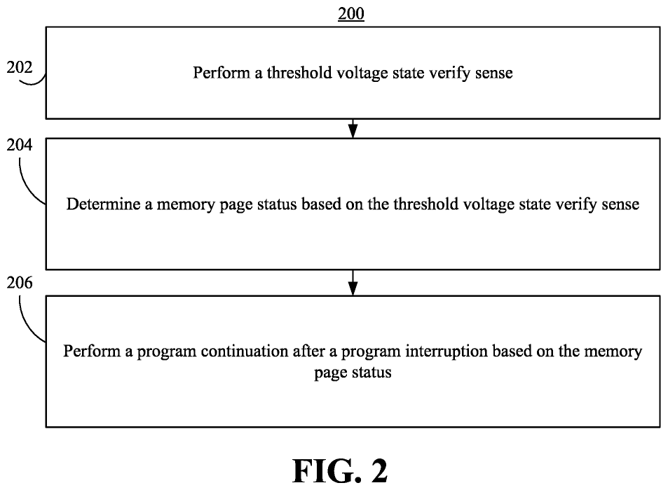

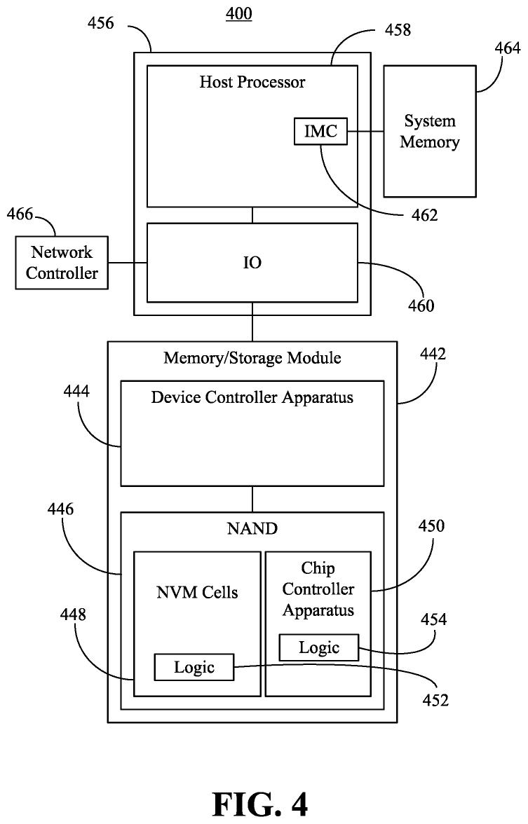

FIG. 2 is a flowchart of an example of a method 200 for management of memory page programming according to an embodiment. The method 200 may generally be implemented in a device, such as, for example, a memory device (e.g., memory device 448 of FIG. 4), a memory controller (e.g., chip controller apparatus 450 of FIG. 4), and/or the like as discussed in greater detail below. Additionally, or alternatively, the method 200 may be implemented in one or more modules as a set of logic instructions stored in a machine- or computer-readable storage medium such as random access memory (RAM), read only memory (ROM), programmable ROM (PROM), firmware, flash memory, etc., in configurable hardware such as, for example, programmable logic arrays (PLAs), field programmable gate arrays (FPGAs), complex programmable logic devices (CPLDs), in fixed-functionality hardware using circuit technology such as, for example, application specific integrated circuit (ASIC), complementary metal oxide semiconductor (CMOS) or transistor-transistor logic (TTL) technology, or any combination thereof.

Illustrated processing block 202 provides for performing a threshold voltage state verify sense.

In some implementations, the threshold voltage state verify sense is performed at a second from last programming level. In other implementations, the threshold voltage state verify sense is performed at one of a last programming level, a second from last programming level, and a third from last programming level. For example, though the second from the last programming level often delivers advantageous performance, the threshold voltage state verify sense could often be performed any of the last three levels.

Illustrated processing block 204 provides for determining a memory page status based on the threshold voltage state verify sense. In such an example, the memory page status is one of erased, programmed with first pass data, and programmed with second pass data based on the threshold voltage state verify sense.

In some implementations, the determination of the memory page status is based on the threshold voltage state verify sense is performed using a single NAND command. For example, the single NAND command is performed with a preexisting read operation. For example, a user issues an atomic sequence “Set Feature” (to activate the procedures herein) followed by preexisting read (e.g., a XP page address or TP page address based on TLC vs. QLC part type) operation, and NAND will output the memory page status as result of that atomic command sequence.

In some examples, the determination the memory page status is performed based on a trimmable threshold.

In some implementations, the determination of the memory page status bypasses use of program flag bytes.

Illustrated processing block 206 provides for performing a program continuation after a program interruption based on the memory page status.

In some implementations, the program interruption is one of a loss of power, a shut down, and a restart.

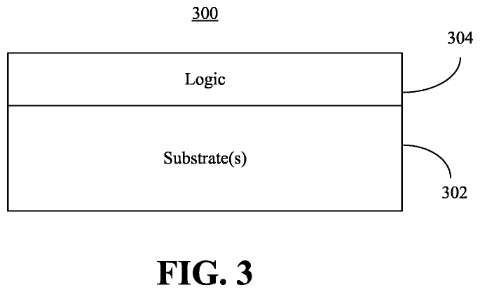

Additional details regarding the various implementations of method 200 are discussed below with regard to FIGS. 3 and 4.

FIG. 3 shows a semiconductor apparatus 300 (e.g., chip, die, and/or package). The illustrated apparatus 300 includes one or more substrates 302 (e.g., silicon, sapphire, gallium arsenide) and logic 304 (e.g., transistor array and other integrated circuit/IC components) coupled to the substrate(s) 302. In an embodiment, the logic 304 implements one or more aspects of the method 200 (FIG. 2), already discussed.

Thus, the logic 304 is to allow a user to distinguish 1^{st}-pass and 2^{nd}-pass states of a Programmed Page after the user identifies that the current page is in non-erased state. For example, a threshold voltage state verify sense is performed by logic 304. A memory page status is determined based on the threshold voltage state verify sense by logic 304. The memory page status is one of erased, programmed with first pass data, and programmed with second pass data based on the threshold voltage state verify sense. A program continuation is performed after a program interruption based on the memory page status by logic 304.

In one example, the logic 304 includes transistor channel regions that are positioned (e.g., embedded) within the substrate(s) 302. Thus, the interface between the logic 304 and the substrate 302 may not be an abrupt junction. The logic 304 may also be considered to include an epitaxial layer that is grown on an initial wafer of the substrate 302.

Turning now to FIG. 4, a performance-enhanced computing system 440 is shown. In the illustrated example, a solid state drive (SSD) 442 includes a device controller apparatus 444 that is coupled to a NAND 446. The illustrated NAND 446 includes a memory device 448 having a set of multi-level NVM cells and logic 452 (e.g., transistor array and other integrated circuit/IC components coupled to one or more substrates containing silicon, sapphire and/or gallium arsenide), and a chip controller apparatus 450 that includes logic 454. The logic 454, which may include one or more of configurable or fixed-functionality hardware, may be configured to perform one or more aspects of the method 200 (FIG. 2), already discussed.

Thus, the logic 452 is to allow a user to distinguish 1^{st}-pass and 2^{nd}-pass states of a Programmed Page after the user identifies that the current page is in non-erased state. For example, a threshold voltage state verify sense is performed by logic 452. A memory page status is determined based on the threshold voltage state verify sense by logic 452. The memory page status is one of erased, programmed with first pass data, and programmed with second pass data based on the threshold voltage state verify sense. A program continuation is performed after a program interruption based on the memory page status by logic 452.

In one example, NAND 446 includes a memory array having a plurality of cell blocks (e.g., NVM cells and logic 452). In such an example, a memory controller (e.g., chip controller apparatus 450) is coupled to the memory array.

The illustrated system 440 also includes a system on chip (SoC) 456 having a host processor 458 (e.g., central processing unit/CPU) and an input/output (I/O) module 460. The host processor 458 may include an integrated memory controller 462 (IMC) that communicates with system memory 464 (e.g., RAM dual inline memory modules/DIMMs). The illustrated IO module 460 is coupled to the SSD 442 as well as other system components such as a network controller 466.

### ADDITIONAL NOTES AND EXAMPLES:

Example 1 includes a semiconductor apparatus comprising one or more substrates and logic coupled to the one or more substrates. The logic is implemented at least partly in one or more of configurable or fixed-functionality hardware. The logic is to: perform a threshold voltage state verify sense; determine a memory page status based on the threshold voltage state verify sense, where the memory page status is one of erased, programmed with first pass data, and programmed with second pass data based on the threshold voltage state verify sense; and perform a program continuation after a program interruption based on the memory page status.

Example 2 includes the semiconductor apparatus of Example 1, where the determination of whether the memory page status is one of erased, programmed with first pass data, and programmed with second pass data based on the threshold voltage state verify sense is performed using a single NAND command.

Example 3 includes the semiconductor apparatus of Example 2, where the single NAND command is performed with a preexisting read operation.

Example 4 includes the semiconductor apparatus of any one of Examples 1 to 3, where the determination of whether the memory page status is one of erased, programmed with first pass data, and programmed with second pass data based on the threshold voltage state verify sense is performed based on a trimmable threshold.

Example 5 includes the semiconductor apparatus of any one of Examples 1 to 4, where the determination of the memory page status bypasses use of program flag bytes.

Example 6 includes the semiconductor apparatus of any one of Examples 1 to 5, where the threshold voltage state verify sense is performed at a second from last programming level.

Example 7 includes the semiconductor apparatus of any one of Examples 1 to 6, where the program interruption is one of a loss of power, a shut down, and a restart.

Example 8 includes a computing system comprising a memory array including a plurality of cell blocks and a memory controller coupled to the memory array. The memory is to: perform a threshold voltage state verify sense; determine a memory page status based on the threshold voltage state verify sense, where the memory page status is one of erased, programmed with first pass data, and programmed with second pass data based on the threshold voltage state verify sense; and perform a program continuation after a program interruption based on the memory page status.

Example 9 includes the computing system of Example 8, where the determination of whether the memory page status is one of erased, programmed with first pass data, and programmed with second pass data based on the threshold voltage state verify sense is performed using a single NAND command.

Example 10 includes the computing system of Example 9, where the single NAND command is performed with a preexisting read operation.

Example 11 includes the computing system of any one of Examples 8 to 10, where the determination of whether the memory page status is one of erased, programmed with first pass data, and programmed with second pass data based on the threshold voltage state verify sense is performed based on a trimmable threshold.

Example 12 includes the computing system of any one of Examples 8 to 11, where the determination of the memory page status bypasses use of program flag bytes.

Example 13 includes the computing system of any one of Examples 8 to 12, where the threshold voltage state verify sense is performed at a second from last programming level.

Example 14 includes a method comprising: performing a threshold voltage state verify sense; determining a memory page status based on the threshold voltage state verify sense, where the memory page status is one of erased, programmed with first pass data, and programmed with second pass data based on the threshold voltage state verify sense; and performing a program continuation after a program interruption based on the memory page status.

Example 15 includes the method of Example 14, where the determination of whether the memory page status is one of erased, programmed with first pass data, and programmed with second pass data based on the threshold voltage state verify sense is performed using a single NAND command.

Example 16 includes the method of claim Example 15, where the single NAND command is performed with a preexisting read operation.

Example 17 includes the method of any one of Examples 14 to 16, where the determination of whether the memory page status is one of erased, programmed with first pass data, and programmed with second pass data based on the threshold voltage state verify sense is performed based on a trimmable threshold.

Example 18 includes the method of any one of Examples 14 to 17, where the determination of the memory page status bypasses use of program flag bytes.

Example 19 includes the method of any one of Examples 14 to 18, where the threshold voltage state verify sense is performed at a second from last programming level.

Example 20 includes the method of any one of Examples 14 to 18, where the threshold voltage state verify sense is performed at one of a last programming level, a second from last programming level, and a third from last programming level.

Example 21 includes a machine-readable storage comprising machine-readable instructions, which when executed, implement a method or realize an apparatus as claimed in any preceding claim.

Example 22 includes an apparatus comprising means for performing the method of any one of Examples 14 to 20.

Technology described herein therefore combines an Erased Page Check with a Vt-State Detection of a programmed memory page using just a single NAND command. Advantageously, the technology improves performance by minimizing system firmware (FW) overhead by providing the Vt State of a memory page with just one single command.

Embodiments are applicable for use with all types of semiconductor integrated circuit (“IC”) chips. Examples of these IC chips include but are not limited to processors, controllers, chipset components, programmable logic arrays (PLAs), memory chips, network chips, systems on chip (SoCs), SSD/NAND controller ASICs, and the like. In addition, in some of the drawings, signal conductor lines are represented with lines. Some may be different, to indicate more constituent signal paths, have a number label, to indicate a number of constituent signal paths, and/or have arrows at one or more ends, to indicate primary information flow direction. This, however, should not be construed in a limiting manner. Rather, such added detail may be used in connection with one or more exemplary embodiments to facilitate easier understanding of a circuit. Any represented signal lines, whether or not having additional information, may actually comprise one or more signals that may travel in multiple directions and may be implemented with any suitable type of signal scheme, e.g., digital or analog lines implemented with differential pairs, optical fiber lines, and/or single-ended lines.

Unless specifically stated otherwise, it may be appreciated that terms such as “processing,” “computing,” “calculating,” “determining,” or the like, refer to the action and/or processes of a computer or computing system, or similar electronic computing device, that manipulates and/or transforms data represented as physical quantities (e.g., electronic) within the computing system's registers and/or memories into other data similarly represented as physical quantities within the computing system's memories, registers or other such information storage, transmission or display devices. The embodiments are not limited in this context.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the platform within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A semiconductor apparatus comprising:
one or more substrates; and
logic coupled to the one or more substrates, wherein the logic is implemented at least partly in one or more of configurable or fixed-functionality hardware, the logic to:
perform a threshold voltage state verify sense;
determine a memory page status based on the threshold voltage state verify sense, wherein the memory page status is one of erased, programmed with first pass data, and programmed with second pass data based on the threshold voltage state verify sense; and
perform a program continuation after a program interruption based on the memory page status.

2. The semiconductor apparatus of claim 1, wherein the determination of whether the memory page status is one of erased, programmed with first pass data, and programmed with second pass data based on the threshold voltage state verify sense is performed using a single NAND command.

3. The semiconductor apparatus of claim 2, wherein the single NAND command is performed with a preexisting read operation.

4. The semiconductor apparatus of claim 1, wherein the determination of whether the memory page status is one of erased, programmed with first pass data, and programmed with second pass data based on the threshold voltage state verify sense is performed based on a trimmable threshold.

5. The semiconductor apparatus of claim 1, wherein the determination of the memory page status bypasses use of program flag bytes.

6. The semiconductor apparatus of claim 1,wherein the threshold voltage state verify sense is performed at a second from last programming level.

7. The semiconductor apparatus of claim 1, wherein the program interruption is one of a loss of power, a shut down, and a restart.

8. A computing system comprising:
a memory array including a plurality of cell blocks; and
a memory controller coupled to the memory array, the memory to:
perform a threshold voltage state verify sense;
determine a memory page status based on the threshold voltage state verify sense, wherein the memory page status is one of erased, programmed with first pass data, and programmed with second pass data based on the threshold voltage state verify sense; and
perform a program continuation after a program interruption based on the memory page status.

9. The computing system of claim 8, wherein the determination of whether the memory page status is one of erased, programmed with first pass data, and programmed with second pass data based on the threshold voltage state verify sense is performed using a single NAND command.

10. The computing system of claim 9, wherein the single NAND command is performed with a preexisting read operation.

11. The computing system of claim 8, wherein the determination of whether the memory page status is one of erased, programmed with first pass data, and programmed with second pass data based on the threshold voltage state verify sense is performed based on a trimmable threshold.

12. The computing system of claim 8, wherein the determination of the memory page status bypasses use of program flag bytes.

13. The computing system of claim 8, wherein the threshold voltage state verify sense is performed at a second from last programming level.

14. A method comprising:
performing a threshold voltage state verify sense;
determining a memory page status based on the threshold voltage state verify sense, wherein the memory page status is one of erased, programmed with first pass data, and programmed with second pass data based on the threshold voltage state verify sense; and
performing a program continuation after a program interruption based on the memory page status.

15. The method of claim 14, wherein the determination of whether the memory page status is one of erased, programmed with first pass data, and programmed with second pass data based on the threshold voltage state verify sense is performed using a single NAND command.

16. The method of claim 15, wherein the single NAND command is performed with a preexisting read operation.

17. The method of claim 14, wherein the determination of whether the memory page status is one of erased, programmed with first pass data, and programmed with second pass data based on the threshold voltage state verify sense is performed based on a trimmable threshold.

18. The method of claim 14, wherein the determination of the memory page status bypasses use of program flag bytes.

19. The method of claim 14, wherein the threshold voltage state verify sense is performed at a second from last programming level.

20. The method of claim 14, wherein the threshold voltage state verify sense is performed at one of a last programming level, a second from last programming level, and a third from last programming level.
